(19) United States
(12) Patent Application Publication
(10) Pub. No.: US 2012/0211058 A1
(43) Pub. Date: Aug. 23, 2012

(54) Antenna for a Wireless Element Affixed to a Solar Module For Enhancing Communication Range

(75) Inventors: Yu-Chih Chen, Danville, CA (US); Hsi Sheng Chen, Fremont, CA (US); Chang-Ming Lin, San Jose, CA (US)

(73) Assignee: E-LIGHTRIC, INC., Monte Sereno, CA (US)

(21) Appl. No.: 13/372,362

(22) Filed: Feb. 13, 2012

Related U.S. Application Data
(60) Provisional application No. 61/444,685, filed on Feb. 18, 2011.

(51) Int. Cl. H01L 31/048

(52) U.S. Cl. 136/251

(57) ABSTRACT

A solar panel includes a wireless device attached to or embedded in the solar panel where the wireless device includes a wireless transceiver circuit and a memory. In one embodiment, the solar panel includes an antenna formed on the metal frame of the solar panel where the antenna is electrically connected to the wireless device to extend a communication range of the wireless device. In another embodiment, the solar panel includes an antenna formed attached to a junction box of the solar panel. The antenna can be a slot antenna or a patch antenna.

### CROSS-REFERENCE TO RELATED APPLICATIONS

This application claims the benefit of U.S. Provisional Patent Application Ser. No. 61/444,685, filed on Feb. 18, 2011, which application is incorporated herein by reference in its entirety.

### FIELD OF THE INVENTION

The invention relates to solar panels and, in particular, to an antenna for a wireless element affixed to a solar panels to enhance the communication range of the wireless element.

### DESCRIPTION OF THE RELATED ART

A solar panel, also referred to as a photovoltaic panel, a solar module, or a photovoltaic module, is a packaged interconnected assembly of solar cells (also referred to as “solar wafers” or “photovoltaic cells”). FIG. 1(a) illustrates a conventional solar panel 1 including an assembly of solar cells 2 interconnected in a two-dimensional array. The array of solar cells is secured by an outer metal frame 7 providing a supporting structure. The solar panel 1 further includes an electrical junction box for housing the electrical connectors to the anode and cathode terminals of the solar panel. The junction box is typically formed on the backside of the solar panel and is not shown in FIG. 1. FIG. 1(b) illustrates a single solar cell 2 including two bus bars 3 forming the electrical contacts of the solar cell. Solar cell 2 includes bus bars 3 formed on the front side (sun up) and also the back side (not shown) of the solar cell. Solar cell 2 are connected in series to form a column of the solar panel 1 by connecting the bus bars on the front side of one solar cell to the bus bars on the back side of the next solar cell and so on. Conductive wires or traces connect the bus bars at the ends of the columns of solar cells to form a serial or parallel connection from the columns of solar cells.

Solar panels use light energy (photons) from the sun to generate electricity through photovoltaic effect (i.e., the photo-electric effect). Because a single solar panel can only produce a limited amount of power, most photovoltaic installations involve connecting multiple solar panels into an array. A photovoltaic system or a solar system typically includes an array of solar panels, an inverter, batteries and interconnection wiring. Solar panels are interconnected, in series or parallel, or both, to create a solar array providing the desired peak output voltage and output current. More specifically, solar cells in a solar panel are connected in series to create an additive voltage and connected in parallel to yield a higher current.

Once the solar cells are assembled into a panel, there is limited access to identify or monitor the individual solar cells. Should any one cell in a solar panel malfunctions, or any one solar panel in a solar array malfunctions, and there will be a claim of warranty replacement or repair by user, but solar panel suppliers have only limited ability to monitor the output performance of the solar cells or solar panels throughout their operational life, in order to validate the warranty claim. This makes product failure analysis and quality correlation study difficult and economically challenging. Inability to remotely monitor individual solar cell or individual solar panel often leads to excess cost over the life time of the panel, also requires more labor maintenance or repairing or expensive replacement.

### SUMMARY OF THE INVENTION

According to one embodiment of the present invention, a solar panel including an array of interconnected photovoltaic cells formed between a top plate and a back sheet and secured by a metal frame includes a wireless device attached to or embedded in the solar panel where the wireless device includes a wireless communication interface and a memory; and an antenna formed on the metal frame of the solar panel where the antenna is electrically connected to the wireless device to extend a communication range of the wireless device.

According to another embodiment of the present invention, a solar panel including an array of interconnected photovoltaic cells formed between a top plate and a back sheet and secured by a metal frame includes a wireless device attached to or embedded in the solar panel where the wireless device comprising a wireless communication interface and a memory; and an antenna formed attached to a junction box of the solar panel where the junction box houses electrical connections between electrical contacts of the photovoltaic cells to cable connectors in the junction box. The antenna is electrically connected to the wireless device to extend a communication range of the wireless device.

The present invention is better understood upon consideration of the detailed description below and the accompanying drawings.

### BRIEF DESCRIPTION OF THE DRAWINGS

FIG. 1(a) illustrates a conventional solar panel including an assembly of solar cells interconnected in a two-dimensional array.

FIG. 1(b) illustrates a conventional single solar cell including two bus bars forming the electrical contacts of the solar cell.

FIG. 2 illustrates the front side and the back side of a solar panel incorporating a wireless device for wireless tracking and performance monitoring according to embodiments of the present invention.

FIG. 3, which includes FIG. 3(a), illustrates a solar panel with a slot antenna integrated on the metal frame according to one embodiment of the present invention.

FIG. 4 illustrates a slot antenna formed on a junction box according to one embodiment of the present invention.

FIG. 5, which includes FIGS. 5(a) and 5(b), illustrates a solar panel with a patch antenna integrated on the metal frame according to one embodiment of the present invention.

FIG. 6 illustrates a patch antenna formed on a junction box according to one embodiment of the present invention.

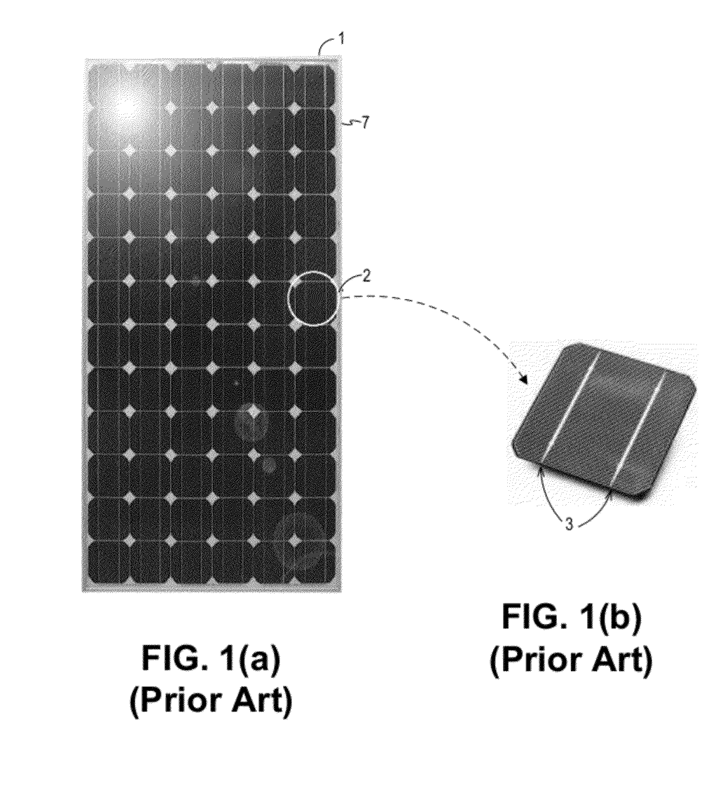

### DETAILED DESCRIPTION OF THE PREFERRED EMBODIMENTS

In accordance with the principles of the present invention, an antenna structure, including a slot antenna and a patch antenna, is formed on a solar panel to enhance the communication range of a wireless device affixed to the solar panel. In some embodiments, the slot antenna or patch antenna is formed on the metal frame of the solar panel. In other embodiments, the slot antenna or patch antenna is formed on a conductive layer affixed to the junction box of the solar panel. The antenna structure enables the wireless device to extend the wireless device's communication range so that the wireless device may communicate with a wireless reader at a greater distance.

In the present description, a solar panel or solar module refers to an assembly of solar cells (or photovoltaic cells or solar wafers) for generating electricity through photovoltaic effect. In general, a solar panel includes an optically transparent layer on the front (sun up) side (also referred to as a “top plate”), allowing light to pass while protecting the solar wafers from the elements (rain, hail, etc.). The solar panel may also include a backside support (also referred to as the “back sheet”), typically made of plastic, such as polyethylene terephthalate (PET) or polycarbonate or other plastic materials. The top plate and the back sheet are secured in a metal frame, such as an aluminum alloy frame. The metal frame seals and protects the peripheral of the solar panel structure as well as provides mechanical supports for installation. A solar panel also includes a junction box for housing the electrical connections from the electrical contacts of the solar cells to the cable connectors in the junction box for electrical connection out of the panel. More specifically, the junction box houses the electrical connectors to the anode and cathode terminals of the solar panel.

In many applications, a wireless device for tracking, authenticating, or performance monitoring, is attached to or embedded in a solar panel for providing remote tracking and/or performance monitoring of the solar panel. Embedding a wireless device in a solar panel for tracking and/or performance monitoring is described in copending and commonly assigned U.S. patent application Ser. No. 12/896,687, filed Oct. 1, 2010, having at least one common inventor hereof, which patent application is incorporated herein by reference in its entirety. In the '687 patent application, the wireless device can be a wireless tracking device for providing tracking function or a wireless tracking and monitoring device for providing both tracking and performance monitoring functions.

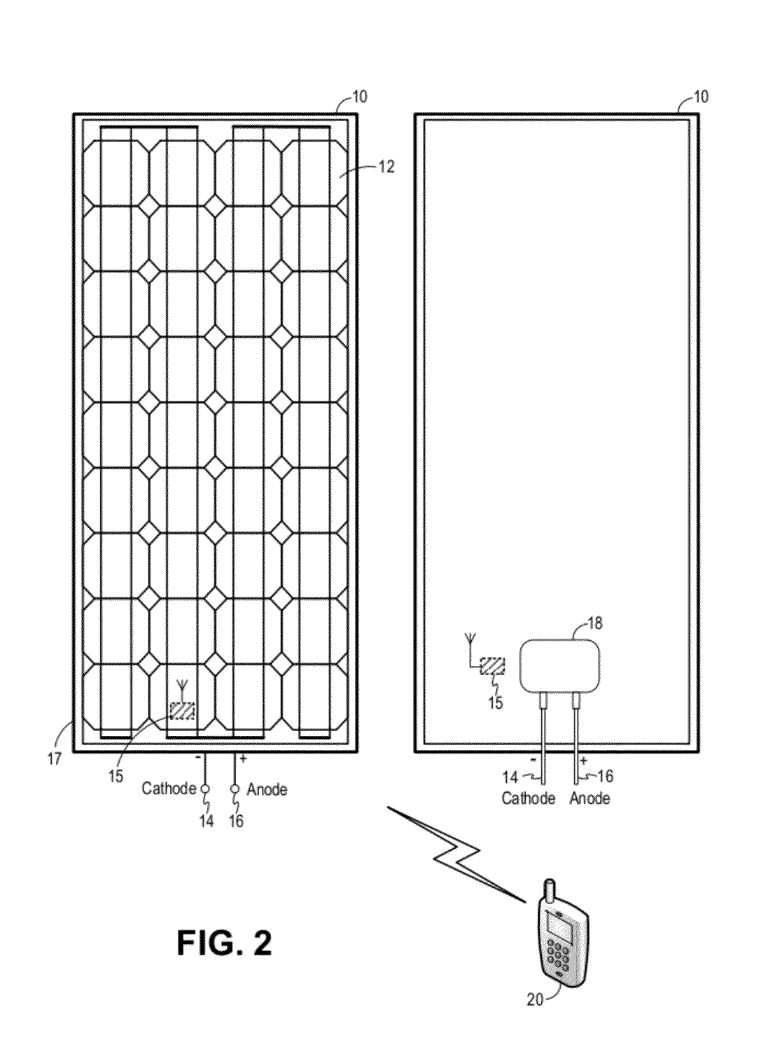

FIG. 2 illustrates the front side and the back side of a solar panel incorporating a wireless device for wireless tracking and performance monitoring according to embodiments of the present invention. Referring to FIG. 2, a solar panel 10 includes an assembly of a two-dimensional array of interconnected solar cells 12 facing the front side, or sun up side, of the solar panel. The solar cells are secured in a metal frame 17 as the supporting structure. Solar panel 10 includes a junction box 18 formed on the back side of the solar panel 10. The junction box 18 houses the electrical connections between the electrical contacts from the solar cells and the cable connectors out of the panel. The solar panel 10 includes external connectors 16 and 18 for connecting to the most positive node (the Anode) and the most negative node (the Cathode) of the solar panel.

To facilitate tracking, authentication, or performance monitoring of the solar panel, a wireless device 15 is attached to or embedded in the solar panel 10 to enable wireless communication with a wireless reader device 20. In some embodiments, the wireless device 15 may be embedded in the solar panel, such as embedded between the top plate and the back sheet of the solar panel. The wireless device 15 may also be formed embedded inside the back sheet. In other embodiments, the wireless device 15 may be affixed or attached to the exposed side of the back sheet of the solar panel 10. When formed on the exposed back sheet of the solar panel, the wireless device 15 may be encapsulated by a protective encapsulant layer. Alternately, the wireless device 15 may be formed inside the junction box 18 of the solar panel. Other ways to incorporate the wireless device 15 into a solar panel are possible. The exact method of integrating the wireless device 15 into the solar panel 10 is not critical to the practice of the present invention.

In embodiments of the present invention, the wireless device includes a memory for storing the identification or identity information of the solar panel or the identification or identity information of the individual solar cells forming the panel. The wireless device further includes wireless communication circuitry for facilitating wireless communication, such as using radio frequency (RF). The wireless device may further include a controller or processor for controlling the operation of the wireless device. When the wireless device also performs monitoring functions, the wireless device includes circuitry to measure one or more operational parameters associated with the solar panel or the solar cells. The measured performance data can be stored in the memory of the wireless device.

However, the solar panel contains many conductive and dielectric materials which can adversely interfere with the wireless device's operation and hinder the performance of the wireless device. More specifically, the communication range of the wireless device can become limited in the presence of these conductive and dielectric materials. In some cases, the wireless device cannot even achieve the as-designed communication distance.

In embodiments of the present invention, an antenna structure is formed on the solar panel to extend the communication range of a wireless device attached to or embedded in the solar panel. The antenna structure enables the wireless device to overcome interferences from the conductive and dielectric materials formed as part of the solar panel. The wireless device is therefore able to maintain at least the as-designed wireless communication range. In some cases, the wireless communication range can be increased beyond the as-designed communication range.

Slot Antenna

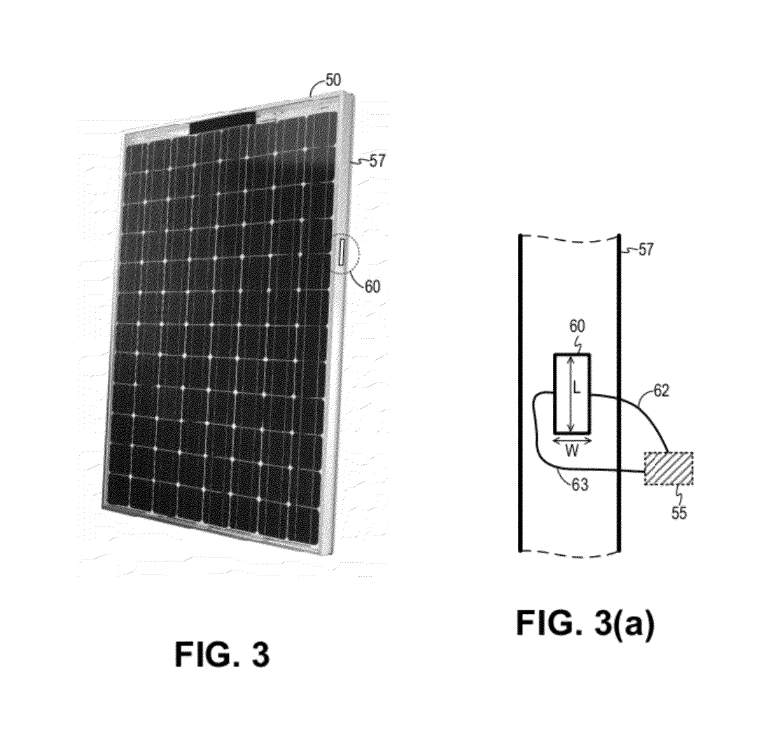

In embodiments of the present invention, a slot antenna is formed on the metal frame of a solar panel and electrically connected to a wireless device attached to or embedded in the solar panel so that the slot antenna extends the communication range of the wireless device. FIG. 3, which includes FIG. 3(a), illustrates a solar panel with a slot antenna integrated on the metal frame according to one embodiment of the present invention. Referring to FIG. 3, a solar panel 50 includes an array of solar cells secured by a metal frame 57. The metal frame 57 is typically an aluminum frame. A slot antenna 60 is formed on the metal frame by forming a cut-out or a slot in the metal frame. FIG. 3(a) illustrates an expanded view of the slot antenna. Referring to FIG. 3(a), the slot antenna 60 is formed by a cut-out in the metal frame 57 of the solar panel 50. The metal frame 57 serves as the ground plane of the slot antenna 60. The cut-out forming the slot antenna has a length of L and a width of W. The length L is selected to be a multiple n of the half wavelength (λ/2) of the operational frequency used in the wireless communication of the wireless device. That is, the length L can be selected as nλ/2, where n is an integer of 1 or more. The width W is selected to be a fraction of the wavelength of the operational frequency and can be selected as a function of the impedance of the transceiver circuit of the wireless device.

Slot antenna 60 further includes antenna terminals 62, 63 which are electrically connected to a wireless device 55 to enhance the communication range of the wireless device. In the present embodiment, the antenna terminals 62, 63 are connected to the mid-points at opposite sides along the length L of the cut-out of the slot antenna. In other embodiments, the antenna terminals 62, 63 can both be connected to the same end of the slot antenna. The placement of the antenna terminals is a function of the length of the slot antenna. As thus formed, the slot antenna 60 has an omnidirectional radiation pattern.

In FIG. 3(a), the connections of the antenna terminals 62, 63 to the wireless device 55 are shown symbolically only. The wireless device 55 may be attached to the back side of the solar panel, such as being affixed to the exposed side of the back sheet. The wireless device 55 may also be attached to the junction box or affixed inside the junction box. In other embodiments, the wireless device 55 may be embedded inside the solar panel, such as being embedded between the front plate and the back sheet of the solar panel. Regardless of how the wireless device 55 is affixed to or embedded in the solar panel 50, the antenna terminals 62, 63 can be electrically connected to the wireless device through metal wires or metal strips or conductive cables. Various methods for forming the electrical connection between the slot antenna 60 and the wireless device 55 can be used. Electrical connection to the antenna terminals 62, 63 at the slot antenna cut-out can be made using soldering or welding.

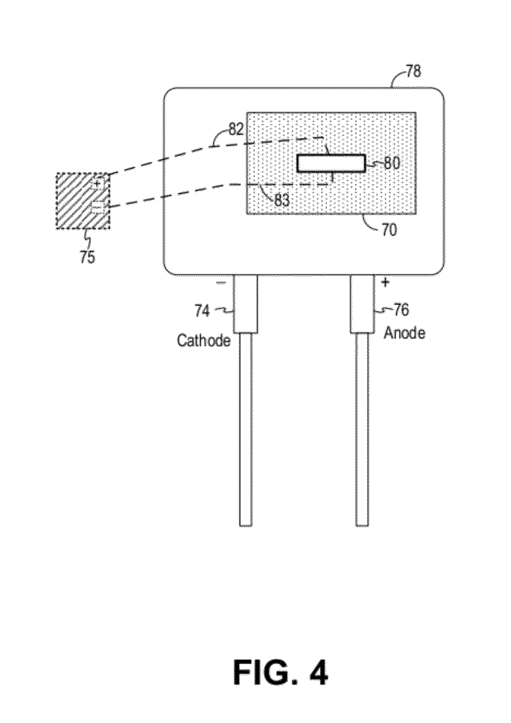

According to embodiments of the present invention, a slot antenna is formed on a metal layer affixed to the junction box of the solar panel. FIG. 4 illustrates a slot antenna formed on a junction box according to one embodiment of the present invention. Referring to FIG. 4, a slot antenna 80 is formed on a metal film 70 where the metal film is affixed to the exposed top surface of a junction box 78. The slot antenna 80 is formed by a cut-out in the metal film 70 and has a length of L and a width of W selected in the same manner as described above. That is, the length L is selected to be a multiple n of the half wavelength (λ/2) of the operational frequency used in the wireless communication of the wireless device, i.e. L=nλ/2, and the width W is selected to be a fraction of the wavelength of the operational frequency and can be selected as a function of the impedance of the transceiver circuit of the wireless device. The metal film 70 functions as the ground plane of the slot antenna 80.

Slot antenna 80 further includes antenna terminals 82 and 83 which are electrically connected to a wireless device 75 to enhance the communication range of the wireless device. In the present embodiment, the antenna terminals 82, 83 are connected to the mid-points at opposite sides along the length L of the cut-out of the slot antenna. In other embodiments, the antenna terminals 82, 83 can both be connected to the same end of the slot antenna. The placement of the antenna terminals is a function of the length of the slot antenna. As thus formed, the slot antenna 80 has an omnidirectional radiation pattern. As described above, the wireless device 75 may be affixed to or embedded in the solar panel to which the junction box 78 is attached. Electrical connections from the slot antenna 80 to the wireless device 75 can be accomplished using metal wires or metal strips or conductive cables. Various methods for forming the electrical connection between the slot antenna 80 and the wireless device 75 can be used. As described above, the wireless device 75 may be attached to the solar panel or embedded in the solar panel.

In embodiments of the present invention, the slot antenna 80 may be encapsulated by an encapsulant to protect the slot antenna. When the slot antenna 80 is encapsulated, the length of the slot antenna can be reduced by a factor of square root of the encapsulant's permittivity.

Patch Antenna

In embodiments of the present invention, a microstrip or patch antenna is formed on the metal frame of a solar panel and electrically connected to a wireless device attached to or embedded in the solar panel so that the patch antenna extends the communication range of the wireless device. In the present description, a patch antenna refers to an antenna formed using a patch of a conductive metal, which is one-half wavelength long, mounted a precise distance above a larger ground plane. In some cases, a spacer made of a dielectric material is placed between the patch and the ground plane.

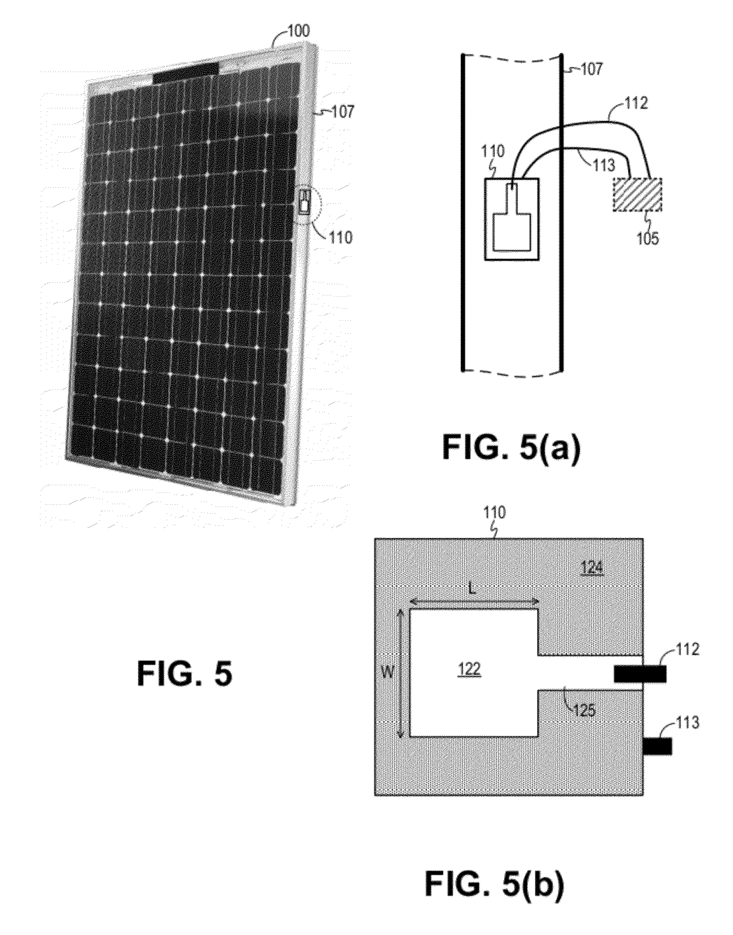

FIG. 5, which includes FIGS. 5(a) and 5(b), illustrates a solar panel with a patch antenna integrated on the metal frame according to one embodiment of the present invention. Referring to FIG. 5, a solar panel 100 includes an array of solar cells secured by a metal frame 107. The metal frame 107 is typically an aluminum frame. A patch antenna 110 is formed attached to the metal frame 107 where the metal frame 107 serves as the ground plane of the patch antenna 110. FIGS. 5(a) and 5(b) illustrate expanded views of the patch antenna. Referring to FIGS. 5(a) and 5(b), the patch antenna 110 is formed using a patch 122 of a conductive metal thin film formed on a dielectric layer 124. The dielectric layer 124 is affixed to the metal frame 107 of the solar panel 100 which serves as the ground plane of the slot antenna 110. In some embodiments, the dielectric layer 124 is adhered to the metal frame 107 using an adhesive or using mechanical fastening means.

In some embodiments, the conductive metal thin film is copper or aluminum or other high conductivity metals. The patch 122 has a length L being half of the wavelength of the operational frequency used in the wireless communication of the wireless device. The dielectric layer 124 has a permittivity ∈ᵣ and a thickness being a small fraction of the operational wavelength of the wireless communication and a function of the operational frequency. The greater the operational frequency, the thinner the dielectric layer is. Typically, the dielectric layer 124 has width and length greater than the area of the patch 122.

A microstrip transmission line 125 extends from an edge of the patch metal 122 to form an antenna terminal 112. The other antenna terminal 113 is formed from the ground plane of the metal frame 107. The antenna terminals 112 and 113 are electrically connected to a wireless device 105 to enhance the communication range of the wireless device. Electrical connections from the patch antenna 110 to the wireless device 105 can be accomplished using metal wires or metal strips or conductive cables. Various methods for forming the electrical connection between the patch antenna 110 and the wireless device 105 can be used.

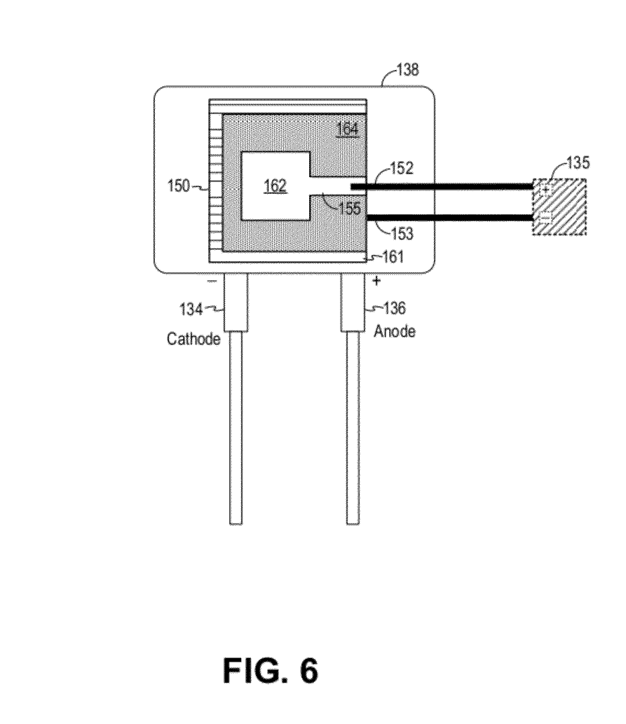

According to embodiments of the present invention, a patch antenna is formed on a metal layer affixed to the junction box of the solar panel. FIG. 6 illustrates a patch antenna formed on a junction box according to one embodiment of the present invention. Referring to FIG. 6, a patch antenna 150 is formed on a metal film 161 where the metal film is affixed to the exposed top surface of a junction box 138. The metal film 161 forms the ground plane of the patch antenna 150. The patch antenna 150 is formed using a patch 162 of a conductive metal thin film formed on a dielectric layer 164. The dielectric layer 124 is further formed on the metal film 161 which is affixed to the exposed front surface of the junction box 138. The dielectric layer 162 may be adhered to the metal film 161 or may be laminated to the metal film.

In some embodiments, the conductive metal thin film forming the patch 162 is copper or aluminum or other high conductivity metals. The patch 162 has a length L being half of the wavelength of the operational frequency used in the wireless communication of the wireless device. The dielectric layer 164 has a permittivity ∈ᵣ and a thickness being a small fraction of the operational wavelength of the wireless communication and a function of the operational frequency, as described above. The dielectric layer 164 has width and length greater than the area of the patch 162.

A microstrip transmission line 155 extends from an edge of the patch metal 162 to form an antenna terminal 152. The other antenna terminal 153 is formed from the metal layer 161 being the ground plane. The antenna terminals 152 and 153 are electrically connected to a wireless device 135 to enhance the communication range of the wireless device. Electrical connections from the patch antenna 150 to the wireless device 135 can be accomplished using metal wires or metal strips or conductive cables. Various methods for forming the electrical connection between the patch antenna 150 and the wireless device 135 can be used. As described above, the wireless device 75 may be attached to the solar panel or embedded in the solar panel.

In embodiments of the present invention, the slot antenna 150 may be encapsulated by an encapsulant to protect the patch antenna.

The above detailed descriptions are provided to illustrate specific embodiments of the present invention and are not intended to be limiting. Numerous modifications and variations within the scope of the present invention are possible. The present invention is defined by the appended claims.

We claim:

1. A solar panel including an array of interconnected photovoltaic cells formed between a top plate and a back sheet and secured by a metal frame, the solar panel comprising:
a wireless device attached to or embedded in the solar panel, the wireless device comprising a wireless transceiver circuit and a memory; and
an antenna formed on the metal frame of the solar panel, the antenna being electrically connected to the wireless device to extend a communication range of the wireless device.

2. The solar panel of claim 1, wherein the antenna comprises a slot antenna, the slot antenna being formed from an opening formed in the metal frame of the solar panel, the metal frame being a ground plane of the slot antenna, the opening having a length being a multiple of a half wavelength of the operational frequency of the wireless device, a pair of antenna terminals being connected to the slot antenna and being connected to the wireless device.

3. The solar panel of claim 2, wherein the pair of antenna terminals are formed along both sides of the length edge of the opening.

4. The solar panel of claim 2, wherein the pair of antenna terminals are formed along one end of the length edge of the opening.

5. The solar panel of claim 2, wherein the opening has a width being a fraction of the wavelength of the operational frequency and a function of the impedance of a transceiver circuit of the wireless device.

6. The solar panel of claim 1, wherein the antenna comprises a patch antenna, the patch antenna comprising a dielectric layer affixed to the metal frame of the solar panel and a metal patch formed on the dielectric layer, the metal frame being a ground plane of the patch antenna, the metal patch having a length being one-half of an wavelength of the operational frequency of the wireless device, the patch antenna further comprising a microstrip transmission line formed extended from an edge of the patch metal, a first antenna terminal being formed at the microstrip transmission line and a second antenna terminal being formed on the ground plane, the antenna terminals being connected to the wireless device.

7. The solar panel of claim 4, wherein the patch metal is formed of a material selected from copper, aluminum, or a high conductivity metal.

8. The solar panel of claim 1, wherein the wireless device is placed between the top plate and the back sheet of the solar panel.

9. The solar panel of claim 1, wherein the wireless device is affixed to an exposed side of the back sheet of the solar panel.

10. A solar panel including an array of interconnected photovoltaic cells formed between a top plate and a back sheet and secured by a metal frame, the solar panel comprising:
a wireless device attached to or embedded in the solar panel, the wireless device comprising a wireless transceiver circuit and a memory; and
an antenna formed attached to a junction box of the solar panel, the junction box housing electrical connections between electrical contacts of the photovoltaic cells to cable connectors in the junction box, the antenna being electrically connected to the wireless device to extend a communication range of the wireless device.

11. The solar panel of claim 10, wherein the antenna comprises a slot antenna, the slot antenna being formed at an opening formed in a metal film attached to an exposed surface of the junction box of the solar panel, the metal film being a ground plane of the slot antenna, the opening having a length being a multiple of a half wavelength of the operational frequency of the wireless device, a pair of antenna terminals being connected to the slot antenna and being connected to the wireless device.

12. The solar panel of claim 11, wherein the pair of antenna terminals are formed along both sides of the length edge of the opening.

13. The solar panel of claim 11, wherein the pair of antenna terminals are formed along one end of the length edge of the opening.

14. The solar panel of claim 11, wherein the opening has a width being a fraction of the wavelength of the operational frequency and a function of the impedance of a transceiver circuit of the wireless device.

15. The solar panel of claim 11, wherein the slot antenna is encapsulated by an encapsulant.

16. The solar panel of claim 10, wherein the antenna comprises a patch antenna, the patch antenna comprising a metal film attached to an exposed surface of the junction box of the solar panel, a dielectric layer attached to the metal film, and a metal patch formed on the dielectric layer, the metal film being a ground plane of the patch antenna, the metal patch having a length being one-half of an wavelength of the operational frequency of the wireless device, the patch antenna further comprising a microstrip transmission line formed extended from an edge of the patch metal, a first antenna terminal being formed at the microstrip transmission line and a second antenna terminal being formed on the metal film, the antenna terminals being connected to the wireless device.

17. The solar panel of claim 16, wherein the patch metal is formed of a material selected from copper, aluminum, or a high conductivity metal.

18. The solar panel of claim 16, wherein the slot antenna is encapsulated by an encapsulant.

19. The solar panel of claim 10, wherein the wireless device is placed between the top plate and the back sheet of the solar panel.

20. The solar panel of claim 10, wherein the wireless device is affixed to an exposed side of the back sheet of the solar panel.
